(19) United States
(12) Patent Application Publication
(10) Pub. No.: US 2009/0295960 A1
(43) Pub. Date: Dec. 3, 2009

(54) PHOTODIODE, PHOTODIODE ARRAY AND IMAGE PICKUP DEVICE

(75) Inventors: Hiroshi INADA, Osaka-shi (JP); Youichi NAGAI, Osaka-shi (JP)

Correspondence Address: VENABLE LLP, P.O. BOX 34385, WASHINGTON, DC, 20043-9998, US

(73) Assignee: SUMITOMO ELECTRIC INDUSTRIES, LTD., Osaka-shi (JP)

(21) Appl. No.: 12/473,919

(22) Filed: May 28, 2009

(30) Foreign Application Priority Data
May 28, 2008 (JP) 2008-139253

(51) Int. Cl. H04N 5/335; H01J 40/00

(52) U.S. Cl. 348/294; 250/200

(57) ABSTRACT

A photodiode that can obtain a clear signal or image in a case in which noise that is not limited to a dark current is high, a photodiode array, and an image pickup device are provided. The photodiode includes a sensor section that is provided on a first semiconductor having a band gap energy which allows input light to be received; a modulated light-emitting section that is positioned behind the sensor section with respect to the input light, and that emits modulated light to the sensor section; and a signal processor that is formed on a second semiconductor which transmits the modulated light, and that is positioned between the sensor section and the modulated light emitting section.

### BACKGROUND OF THE INVENTION

1. Field of the Invention

The present invention relates to a photodiode that is targeted for signal light which is in any wavelength range, more particularly, signal light which is in the near infrared range, a photodiode array in which the photodiodes are one dimensionally or two dimensionally arranged, and an image pickup device utilizing the photodiode array.

2. Description of the Related Art

III-V compound semiconductors have drawn attention as compound semiconductors having band gap energies that correspond to light having a wavelength which is in the near infrared range or light having a wavelength that is longer than the longest wavelength in the near infrared range, and research and development of the III-V compound semiconductors have progressed. For example, a night vision camera is disclosed, which receives natural light such as night glow by using a photodiode array in which photodiodes, each of which has a light-receiving layer of InGaAS whose lattice can be matched to the lattice of InP, are arranged on an InP substrate (see Marshall J. Cohen and Gregory H. Olsen “Near-IR imaging cameras operate at room temperature”, LASER FOCUS WORLD, June 1993, pp. 109-113). With this night vision camera, an image can be picked up using natural light without using any artificial lighting regardless of weather at night or rainy.

However, it is difficult to obtain a clear image with the above-mentioned night vision camera. One of the main reasons for this is that a dark current is large in photodiodes. In the related art, an output in a case in which no light is input and an output in a case in which light is input are alternately measured to obtain the difference between the outputs, and are stored as measured values, thereby obtaining an image. In a case in which the dark current that is the main one factor of noise is large, when no light is input, the input level of light is almost occupied by an input level corresponding to the dark current. Even in a case in which light is input, when the input level of the light is low, an output (a current or voltage) of each picture element that is to be used for obtaining an image is buried in an output that is caused by the dark current. Accordingly, it is difficult to obtain a clear image in this case. Furthermore, generally, the input level of light that is in the near infrared range, such as the above-mentioned night glow, is not expected to be high in many cases. Thus, in order to extend the application of the night vision camera, it is necessary that a case in which noise that is not limited to a dark current is high be dealt with (i.e., it is necessary that a clear image be obtained). Additionally, means for obtaining a clear signal (having a high S/N ratio) or a clear image in a case in which a noise level is high as described above is useful for receiving signal light that is in any wavelength range which is not limited to the near infrared range.

### SUMMARY OF THE INVENTION

Accordingly, it is an object of the present invention to provide a photodiode capable of receiving a clear signal or image in a case in which noise that is not limited to a dark current is high, a photodiode array, and an image pickup device.

A photodiode according to an aspect of the present invention includes the following: a sensor section that is provided on a first semiconductor having a band gap energy which allows input light having a wavelength that is in a target wavelength range to be received; a modulated light-emitting section that is positioned behind the sensor section with respect to the input light, and that is configured to emit, to the sensor section, modulated light having a band gap energy which is higher than that of the sensor section; and a signal processor that is formed on a second semiconductor which transmits the modulated light, and that is positioned between the sensor section and the modulated light-emitting section.

With this configuration, modulation in which the modulated light is superimposed is performed instead of modulation in which the input light is reduced by a chopper. Accordingly, sensitivity can be increased. Thus, the photodiode can be obtained, which is capable of detecting, at a high sensitivity as a signal, even input light (signal light) whose intensity is extremely low. Furthermore, modulation is performed using a multilayer structure (a surface that the input light enters/the sensor section (the first semiconductor)/the signal processor (the second semiconductor)/the modulated light-emitting section). This multilayer structure is useful for miniaturization of the photodiode and a product using the photodiode.

The signal processor may include a detector, and the detector may be configured to drive the modulated light-emitting section, configured to read an output that is generated in the sensor section by the input light and the modulated light, and configured to detect a signal of the input light by using lock-in detection. With this detector, the modulated light is emitted to the sensor section at a frequency that is matched to a frequency at which reading is performed, and a direct current component of a mixed signal is read, thereby removing noise components, so that the signal can be detected. As a result, even when a noise level is high and the intensity of the input light is low, a signal having a high S/N ratio can be obtained.

The input light that is in the target wavelength range may be light that is in a near infrared range. Accordingly, sensing, image pickup, and so forth using light that is in the near infrared range, such as night glow, can be performed. In this case, any compound semiconductor, such as an InP-based compound semiconductor, or an InGaAs-based compound semiconductor (that contains or does not contain N, Sb, P, or the like), can be used as a semiconductor having a band gap energy which allows the light that in the near infrared range to be received.

The second semiconductor may be silicon. Accordingly, when the input light that is in the target wavelength range is light that is in the near infrared range, because silicon transmits the light that is in the near infrared range, the modulated light can be irradiated onto the sensor section via the silicon substrate on which the processor is formed, and modulation can be easily performed. More particularly, there are many achievements in production processes using silicon substrates, and existing facilities for the production processes have been improved. Thus, silicon substrates are suitable for low-cost mass-production of the photodiode.

The signal processor may include a complementary metal oxide semiconductor (CMOS) circuit or a charge coupled device (CCD) circuit. Accordingly, charge corresponding to carriers that are generated in the sensor section by photoelectric conversion is stored in a predetermined time, and a voltage signal or the like can be easily obtained using the amount of the stored charge.

The modulated light-emitting section may be formed using a surface emitting device. Accordingly, the modulated light-emitting section can be compactly formed.

In a photodiode array according to another aspect of the present invention, the two or more photodiodes according to Claim 1 are one dimensionally or two dimensionally arranged. The sensor sections are formed on one common substrate of the first semiconductor, and the signal processor is formed on one common substrate of the second semiconductor. With this configuration, the photodiode array can be miniaturized. While wiring lengths are being reduced, an image can be efficiently formed. Thus, the photodiode array can be used as the main element of, for example, an image pickup device.

The modulated light-emitting section is formed as one emitting section that is common to the two or more photodiodes. Accordingly, the modulated light-emitting section can be produced as a device having a simple configuration. The production process of the modulated light-emitting section is also simplified, and the modulated light-emitting section can be produced at a low cost.

An image pickup device according to another aspect of the present invention is an image pickup device for detecting a signal of input light and forming an image. The image pickup device includes the following: a plurality of light-receiving sections that are formed in a one-dimensional or two-dimensional arrangement on a light-receiving semiconductor; and a modulated light-emitting section configured to irradiate the plurality of light-receiving sections with modulated light in such a manner that the modulated light is superimposed on the input light.

With this configuration, in the image pickup device, modulation is performed in such a manner that the modulated light is superimposed on the input light, whereby a clear image can be obtained even when a noise level is high and the input light is extremely weak. Note that the light-receiving sections in the image pickup device may be regarded as respective photodiodes corresponding to picture elements, or that the light-receiving sections, in a narrower meaning, may be regarded as light-receiving sections which are included in the photodiodes and in which light is received.

The modulated light may be irradiated onto the plurality of light-receiving sections from a surface that is positioned on a side which is opposite a side of a surface that the input light enters. Accordingly, modulation can be performed in such a manner that the modulated light is irradiated onto the light-receiving sections without interruption of the input light. Note that, although a term “irradiation” is used for a case in which the modulated light enters the light-receiving sections, the term does have a particular meaning, and the meaning of “irradiation” can be regarded as the same meaning of “entering”.

The image pick up device may include a signal processor configured to drive the modulated light-emitting section, configured to read, from each of the plurality of light-receiving sections, an output that is generated by the input light and the modulated light, and configured to detect a signal that is caused by the input light. The signal processor can be formed on a semiconductor for forming a circuit which transmits the modulated light, and can be configured so that it is positioned between the plurality of light-receiving sections and the modulated light section. Accordingly, a clear image can be obtained while miniaturization of the image pickup device is being realized.

The light-receiving semiconductor may be a semiconductor that is capable of receiving the input light which is in a near infrared range, and the semiconductor for forming a circuit may be silicon. Accordingly, by using silicon with which there are many achievements in production processes using existing facilities, the signal processor that receives a signal for each of the light-receiving sections can be formed. As a result, the miniaturized image pickup device for the near infrared range can be obtained, which is capable of performing signal processing for each of the light-receiving sections.

Any of the photodiode, the photodiode array, and the image pickup device according to the aspects of the present invention can obtain a clear signal or image even when noise is high.

### BRIEF DESCRIPTION OF THE DRAWINGS

FIG. 1 is a sectional view of a photodiode according to a first embodiment of the present invention;

FIG. 2 is an illustration for explaining lock-in detection that is performed in the photodiode shown in FIG. 1;

FIG. 3 is a partial sectional view of an image pickup device (a photodiode array) according to a second embodiment of the present invention;

FIG. 4 is a plan view of the image pickup device shown in FIG. 3;

FIG. 5 is a diagram for explaining signal processing that is performed in a CMOS section;

FIG. 6 is an illustration for explaining a circuit that converts the amount of stored charge which is stored in a photodiode to a voltage, and that amplifies the voltage; and

FIG. 7 is a diagram for explaining signal processing that is performed in a digital camera in which the image pickup device shown in FIG. 3 is embedded.

### DESCRIPTION OF THE PREFERRED EMBODIMENTS

### First Embodiment

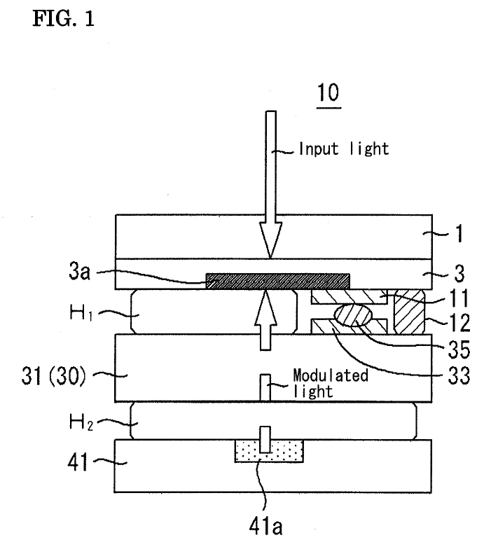

FIG. 1 is a diagram of a photodiode 10 according to a first embodiment of the present invention. Regarding the photodiode 10, a light-receiving layer 3 is formed under a semiconductor substrate 1, and a light-receiving section 3a is formed in the light-receiving layer 3. The semiconductors that are used in this case correspond to first semiconductors or light-receiving semiconductors. A first conductivity-type region (not illustrated) is formed in the light-receiving section 3a, and is in ohmic contact with a first conductivity type side electrode 11. Furthermore, any one portion of the semiconductor substrate 1, the light-receiving layer 3, and a buffer layer (not illustrated) is formed as a second conductivity-type region. The second conductivity-type region has the ground potential, and is in ohmic contact with a second conductivity type side electrode 12. A p-n junction, a p-i junction, or an n-i junction is formed on an interface of the first conductivity-type region, which is included in the light-receiving section 3a, on the light-receiving layer 3 side. A reverse bias voltage is applied to the junction, thereby forming a depletion layer on the light-receiving layer 3 side. The depletion layer can be regarded as the light-receiving section 3a. The semiconductor substrate 1 is formed of a material that transmits light having a wavelength which is in a range of the wavelength of light that is to be received by the light-receiving section 3a.

A signal processor 31 is formed on a semiconductor substrate 30 (a second semiconductor or a semiconductor for forming circuits). The signal processor 31 is positioned below an epitaxial layer, which includes the semiconductor substrate 1 and the light-receiving section 3a, (on a side that is opposite a side of a surface that input light enters) so that a spacer H1 exists between the epitaxial layer and the semiconductor substrate 30. The first conductivity type side electrode 11 is electrically connected to a signal input pad 33 of the signal processor 31 via a solder bump 35. Furthermore, the second conductivity type side electrode 12 is electrically connected to the ground potential.

A modulated light-emitting device 41 including an emitting section 41a is disposed below the semiconductor substrate 30, on which the signal processor 31 is provided, (on a side that is opposite a side of the light-receiving section 3a) so that a spacer H2 exists between the semiconductor substrate 30 and the modulated light-emitting device 41. The modulated light-emitting device 41 emits modulated light to the light-receiving section 3a. It is necessary that the modulated light be light having a wavelength which is in a range of the wavelength of light that is to be received by the light-receiving section 3a. Additionally, it is necessary that the semiconductor substrate 30 including the signal processor 31 be formed of a material which transmits the modulated light. Furthermore, it is preferable that the spacers H1 and H2 be also formed of a material which transmits the modulated light.

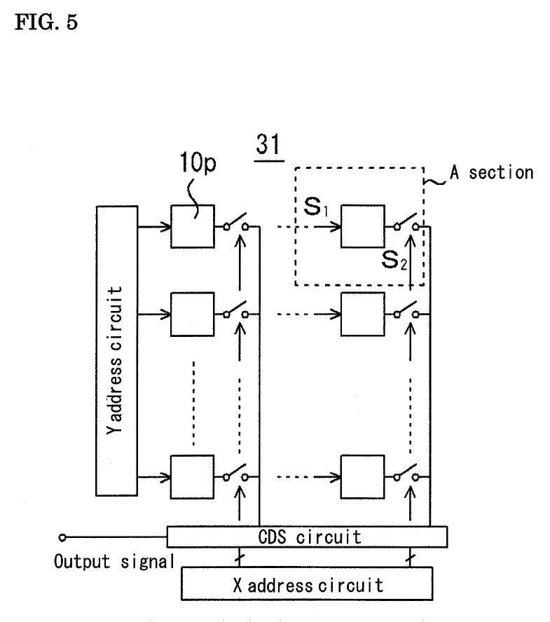

Referring to FIG. 1, the light-receiving section 3a is irradiated with the input light and the modulated light, and photoelectric conversion is performed by both the input light and the modulated light. The signal processor 31 performs signal processing on a current that is obtained by photoelectric conversion. In other words, the light-receiving section 3a receives light for a predetermined time, thereby generating photoinduced charge. The photoinduced charge is stored in the light-receiving section 3a. The stored photoinduced charge is read as a current by the signal processor 31. The read current is processed still as a current (CCD). Alternatively, the read current is converted to a voltage, and the voltage is amplified (CMOS). The method for processing the read current differs depending on the type of the signal processor 31. However, in any case, a voltage that is obtained by conversion is output from the signal processor 31. A method in which an output from the light-receiving section 3a is processed with CMOS circuits will be described below in detail with reference to FIG. 5.

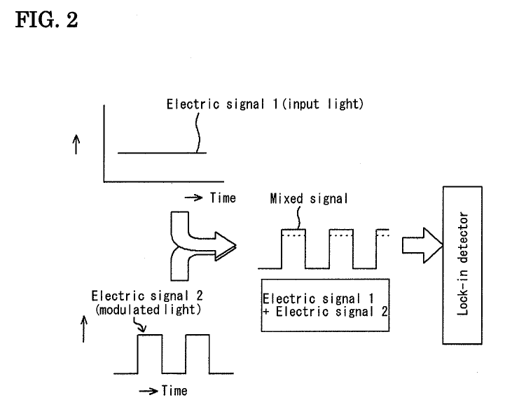

FIG. 2 is an illustration showing steps, i.e., superimposing an electric signal 1, which is caused by the input light, and an electric signal 2, which is caused by the modulated light, on each other, thereby forming a mixed signal, and detecting the mixed signal by using lock-in detection. FIG. 2 is a schematic illustration, and is an illustration which is provided under the assumption that the electric signal 1 and the electric signal 2 are separately generated. In reality, regarding the electric signal 1, an electric signal that is caused by only the input light is extremely weak, and fixed noise that is caused by a dark current or the like is superimposed. In such a case, the present invention aims to detect a signal that has a high S/N ratio and that is caused by the input light. In other words, the target case is a case in which high noise is included in the electric signal 1. In FIG. 2, the electric signal 2 is illustrated under the assumption that the electric signal 2 does not include noise. Note that noise that is caused by a photoelectric conversion section of an epitaxial multilayered body, which includes the semiconductor substrate 1, the light-receiving layer 3, and the light-receiving section 3a, is a problem that is dealt with in the first embodiment.

Supposing that, typically, noise is caused by a dark current which exists in the light-receiving layer 3 or the light-receiving section 3a, and that the noise is included in the electric signal 1, the noise is illustrated in FIG. 2. In other words, supposing that all of the noise which is caused by the photodiode is included in the electric signal 1, the electric signal 2 is illustrated in FIG. 2. When noise is generated in proportion to the intensity of received light, it is necessary to consider the noise. Even for any noise, by performing lock-in detection, a direct current component that is caused by noise or the like is removed, and a signal that is caused by the input light is selected with a high accuracy, whereby the signal having a high S/N ratio can be obtained.

A lock-in detector can easily remove a direct current component from the mixed signal by performing frequency analysis. Supposing that there is a low possibility that the input light and noise are influenced by each other to have the same frequency, frequency components that are caused by noise can be removed by performing frequency analysis. For example, for a discrete photodiode, a frequency at which reading is performed can be set to about 200 kHz. A modulation frequency of the modulated light for performing lock-in detection is set to a frequency that is the same as the frequency at which reading is performed, and a direct current component that is included in the mixed signal is read, whereby only a signal excluding noise components can be read. Furthermore, even when noise increases proportionately with the intensity of the input light, the modulated light can have any waveform. Since the pattern of the waveform is already known, a large number of noise components can be removed from the mixed signal. As a result, lock-in detection is performed in such a manner that frequency analysis is performed on the mixed signal, whereby a signal that is caused by the input light and that has a high S/N ratio can be obtained.

The signal processor 31 can be formed on the semiconductor substrate 30, on which the photodiode 10 shown in FIG. 1 can be provided, so as to include the lock-in detector. As a result, the photodiode 10 can be easily miniaturized. The modulated light is transmitted through the semiconductor substrate 30. However, since the first conductivity type side electrode 11, the second conductivity type side electrode 12, the solder bump 35, the signal input pad 33, and so forth are formed of metal, the modulated light is not transmitted through these metallic portions. However, the metallic portions do not cover the entire region of the light-receiving section 3a. Because only one portion of the region of the light-receiving section 3a is influenced, the above-described scheme involving “irradiating modulated light, forming a mixed signal, and performing lock-in detection” is not changed.

### Second Embodiment

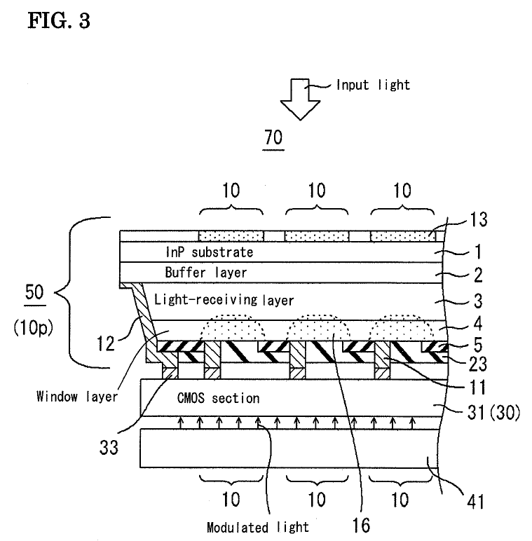

FIG. 3 is a diagram showing one portion of an image pickup device (one example of a product using a photodiode array) 70 according to a second embodiment of the present invention. A target wavelength range is the near infrared range. An InP substrate 1 is used, and an InGaAs-based compound semiconductor is used for a light-receiving layer 3. The InP substrate and the InGaAs-based compound semiconductor that are used in this case correspond to first semiconductors or light-receiving semiconductors. The image pickup device 70 includes the following main elements: a sensor section 50 in which a plurality of picture elements are provided; a CMOS section 31 that is positioned below the sensor section 50, and that corresponds to a signal processor; and a vertical cavity surface emitting laser (VCSEL) 41 that is positioned below the CMOS section 31, and that corresponds to a modulated light-emitting section. The VCSEL 41 emits near infrared light having a wavelength that is in the range of 1.2 μm to 3.0 μm. A semiconductor substrate on which the CMOS section 31 is formed is a silicon substrate 30, and the silicon substrate 30 corresponds to a second semiconductor or a semiconductor for forming circuits.

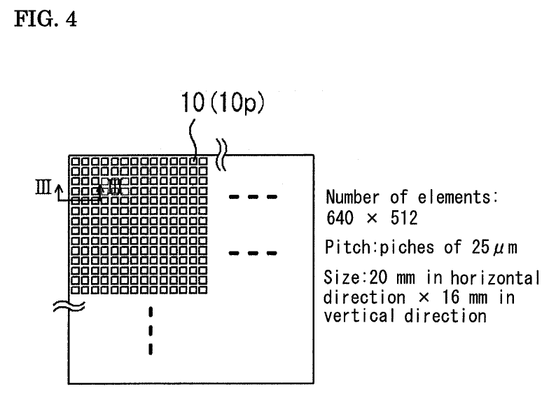

FIG. 4 is a plan view of the image pickup device 70 when viewed from the light incident side. FIG. 3 is a sectional view of the image pickup device, which is taken along the line III-III shown in FIG. 4. Referring to FIG. 3, the image pickup device 70 has the following configuration. In other words, an epitaxial multilayered body (an n-type buffer layer 2, a light-receiving layer 3, and an InP window layer 4) is formed on the common InP substrate 1. A p-type impurity is implanted into the inside of the epitaxial multilayered body from the InP window side 4, thereby forming p-type regions 16. P-n junctions or p-i junctions are formed at the boundaries of the p-type regions 16. Light-receiving sections are formed in depletion layers that extend from the corresponding p-n junctions or p-i junctions to corresponding n-type regions or i-type regions of the light-receiving layer 3.

A impurity-diffusion mask pattern 5 remains together with a polyimide film pattern of a protective film 23 that is formed on the impurity-diffusion mask pattern 5. Picture elements that each include one photodiode 10p, sensor units, or photodiodes 10 are provided at pitches of 25 μm in the vertical and horizontal directions in a region having a size of 20 mm in the horizontal direction by 16 mm in the vertical direction as shown in FIG. 4. The total number of arranged picture elements is 640×512=327,680. The arrangement of the picture elements is shown as one example, and may be changed in accordance with a product specification, as a matter of course.

Both p-electrodes 11, each of which is electrically connected to a corresponding one of the p-type regions 16 of the epitaxial layers, and n-electrodes 12, which are provided in the n-type buffer layer 2 that is directly attached to the common InP substrate 1, are connected to the CMOS section 31, which is a signal processor, via junction bumps 33 such as solder bumps. AuZu is used for the p-electrodes 11. Furthermore, AuGeNi is used for the n-electrodes 12. Each of the p-electrodes 11 and n-electrodes 12 is formed so that ohmic contact is ensured for it. A TiPt-based metal may be used for the p-electrodes 11 instead of the above-mentioned AuZn-based metal. It is preferable that an anti-reflection (AR) film 13 be placed on the surface of the InP substrate 1 which the input light enters so that efficiency of reception of the input light can be increased. In the above-described configuration, the photodiodes 10p that are arranged in a matrix form serve as photocurrent generators of the light-receiving sections of the respective photodiodes 10. The photodiodes 10 are configured to serve as units of picture elements that include the CMOS section 31 and the VCSEL 41, and each of the photodiodes 10 corresponds to a photodiode in a corresponding one of the picture elements.

The VCSEL 41 that is configured to serve as a modulated light-emitting device has an excellent responsivity, and can emit modulated light having a single wavelength. Because it is not necessary that surface emitting be performed for each of the picture elements, a surface emitting laser that is common to the picture elements and that has a large size may be used. Furthermore, as in the case of a backlight for a liquid crystal, bar emitting bodies having an excellent responsivity may be placed at sides of a light guide plate that is positioned in parallel with the light-receiving layer 3. A configuration may be used, in which modulated light is partially reflected by inclined reflection units while the modulated light that enters the light guide plate from the sides thereof is propagating through the light guide plate, and in which the modulated light is emitted from the surface of the light guide plate to the light-receiving layer 3.

The input light enters the InP substrate 1 via the AR film 13 that is formed on the rear surface of the InP substrate 1, and is received in the depletion layers that extend from the corresponding p-i junctions or p-n junctions which are formed on an interface between the p-type regions 16 and the light-receiving layer 3. A reverse bias voltage for forming each of the depletion layers is applied between a corresponding one of the n-electrodes 12 and a corresponding one of the p-electrodes 11. The depletion layer functions as a capacitance, and stores, in a charge storage period that is determined by the CMOS section 31, charge that is obtained by photoelectric conversion. It is preferable that a multiple quantum well structure which is formed of InGaAs, Ga₁₋ₓInₓN_{y}As_{1-y-z-w}Sb_{z}P_{w}(0.4≦x≦0.8, 0≦y≦0.2, 0≦z≦0.2, and 0≦w≦0.05), or InGaAs/GaAsSb, or the like be used for the light-receiving layer 3 as described above. Electron-hole pairs are generated in each of the light-receiving sections by photoelectric conversion. Holes among the electron-hole pairs move as signal charge from each of the p-type regions 16 via a corresponding one of the p-electrodes 11, and the amount of the signal charge is read for a corresponding one of the picture elements by the CMOS section 31. Scanning is performed using driven pulses, thereby reading the amounts of signal charge for all of the picture elements are sequentially performed.

Next, lock-in detection that is performed in the image pickup device will be described. For moving pictures, because 30 frames are scanned for one second, 33 ms per frame is necessary. For example, when lock-in detection is applied to an image pickup device having eighty thousand picture elements, i.e., 320×256 picture elements, a time per picture element is 0.4 μs, and reading is performed at a frequency of 2.5 MHz. When lock-in detection is performed, reference radiation (modulated light) is irradiated at a modulation frequency of 2.5 MHz, thereby generating a mixed signal. The mixed signal is processed by a low-pass filter having a narrow band to extract a direct current component, thereby removing noise. Accordingly, only a signal excluding noise components can be read. Because a clock of a reference signal for lock-in detection ranges from 200 kHz, which is used for a typical case, to about 5 MHz, which is used for a specific case, the above-described lock-in detection can be easily realized. Furthermore, application of lock-in detection to an image pickup device having 64×64 picture elements will be described as another example. A frequency at which reading is performed in this image pickup device is 130 kHz. Thus, lock-in detection can be performed with a lock-in device that is used for a typical case. In any of the above-described examples, an S/N ratio of a signal can be increased for each photodiode as a result of lock-in detection. Additionally, when a frame period and the reference signal are synchronized with each other, it is preferable that the modulation frequency which is in the range of 30 Hz to 200 Hz be used although depending on requirements to perform a high-speed image analysis process.

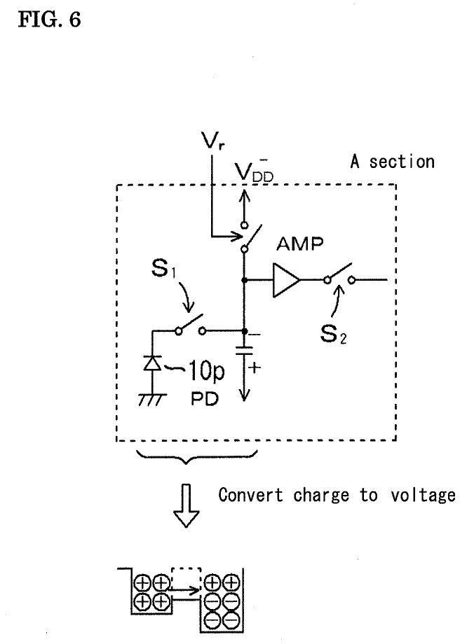

FIG. 5 is an illustration for explaining a signal processing method that is performed in the typical CMOS section 31. Furthermore, FIG. 6 is an enlarged view of an A section including switching units S1 and S2 shown in FIG. 5, and is a view for explaining a mechanism for converting the amount of signal charge corresponding to holes which are generated in each of the photodiodes 10p to a voltage, and for amplifying the voltage. Referring to FIG. 5, a horizontal line is selected by a switching signal that is supplied from a Y address circuit which selects any one of horizontal lines. Next, one photodiode is selected by an X address circuit from among the photodiodes 10p of the picture elements that are arranged in a matrix form. A voltage corresponding to the amount of signal charge that is stored in a predetermined time as described above is read to an output signal line. The photodiodes 10p are sequentially selected in a scanning order.

The CMOS section 31 converts the amounts of signal charge that is stored in the photodiodes 10p, to signal voltages so that the CMOS section 31 obtains, for each of the photodiodes 10p, a corresponding one of the signal voltages. The CMOS section 31 amplifies the signal voltages, and sequentially reads the signal voltages, thereby obtaining electric signals. In typical CMOS circuits, electrons among electron-hole pairs that are generated by photoelectric conversion move to a current-to-voltage converter. However, because the amount of signal charge corresponding to holes is read in the image pickup device shown in FIG. 3, it is necessary that appropriate modifications be made to a circuit configuration. FIG. 6 shows an example in which such modifications have been made to the circuit configuration. In CMOS circuits, when voltage amplification is performed in the respective picture elements, black levels are different from one another because of a variation in threshold levels of MOS transistors, and the differences cause noise. Voltages corresponding to the different black levels are clamped to a fixed value by a correlated double sampling (CDS) circuit shown in FIG. 5. The differences between the clamped voltages corresponding to the black levels and signal levels are obtained, whereby influences of the differences among the threshold levels of MOS transistors can be removed.

Characteristics in a case in which the CMOS section 31 is used as a signal processor are as follows. (1) Low power consumption can be realized. (2) Random access can be performed. In other words, not only signals can be sequentially read from the photodiodes 10p of the respective picture elements, but also the signals can be randomly read from the respective photodiodes 10p. (3) The image pickup device can operate with a single power source and a single clock. Accordingly, the number of wiring patterns that are provided between the epitaxial multilayered body, in which the photodiodes 10p are formed, and the CMOS section 31 can be minimized. Thus, this is an advantage in view of radiated noise. (4) The entire control circuit including the signal processor, such as a drive section for reading the amounts of signal charge by scanning, and so forth can be configured as one chip.

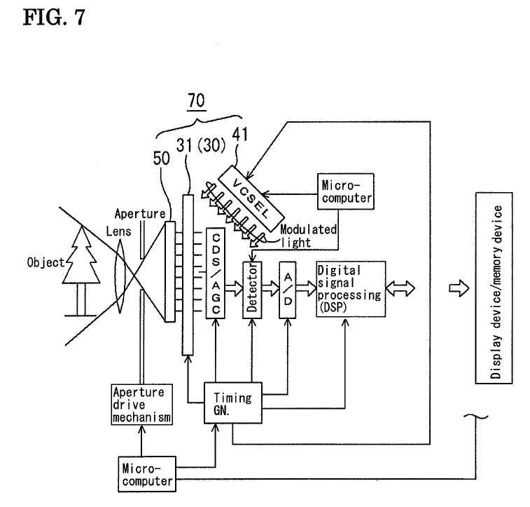

FIG. 7 is a diagram showing a process of signal processing that is performed in a digital camera in which the image pickup device (the photodiode array) 70 according to the second embodiment is embedded. Referring to FIG. 7, the image pickup device 70 according to the second embodiment includes the following: an epitaxial multilayered body 50 that includes the light-receiving layer 3; the CMOS section 31 that receives signals from the respective photodiodes 10p which are formed in the epitaxial multilayered body 50, and that performs signal processing on the received signals; and the VCSEL 41 that is positioned behind the CMOS section 31, and that emits modulated light to the light-receiving layer 3 through the CMOS section 31. The CMOS section 31 is formed on a semiconductor substrate such as a silicon substrate. Accordingly, it is preferable that processing circuits, such as a CDS/automatic gain control (AGC) circuit shown in FIG. 7, a detector that performs lock-in detection, and so forth, which serve as the following stages of the CMOS section 31 be formed on the same silicon substrate 30. The circuits including the detector and so forth can be regarded as one portion of the signal processor. The silicon substrate on which the signal processor is formed is inexpensive. Additionally, there are many achievements in production processes using silicon substrates, and devices for the production processes have been improved. Thus, silicon substrates are suitable for mass-production of the image pickup device from the economical point of view.

Referring to FIG. 7, a signal from which predetermined noise has been removed by the CDS circuit is input to the AGC circuit. In the AGC circuit, a gain of an amplifier is controlled by a central processing unit (CPU), and a strength level of the signal that is necessary for an analog-to-digital (A/D) converter is obtained by the AGC circuit together with an aperture drive mechanism and so forth. The detector may be provided as the previous stage of the AGC circuit. The detector performs lock-in detection. In a case in which, for example, noise that is difficult to be processed by the CDS circuit or the like and that is caused by a dark current is high, and in which input light is low, a mixed signal is generated using the input light and modulated light that is emitted from the VCSEL 41. After that, a signal having a high S/N ratio can be obtained. In other words, in a case in which an electric signal that is caused by only the input light before the modulated light is emitted is extremely weak, and in which the electric signal is buried in noise (the electric signal having a low S/N ratio), the mixed signal is formed by adding the modulated light to the input light, whereby the signal that has a high S/N ratio and that is caused by the input light can be detected.

In the image pickup device 70 shown in FIG. 7, as described above, the CDS/ACG circuit, the detector, the A/D converter, and so forth can be formed all together on the semiconductor substrate 30, on which the CMOS section 31 is formed. It can be regarded that the signal processor includes the circuits including the detector. The VCSEL 41, which is a modulated light-emitting device, emits modulated light that is in the near infrared range to the arranged photodiodes, which are formed on the InP substrate, via the silicon substrate 30. Silicon is a material that has a low absorption coefficient of light which is in the near infrared range, and that transmits near infrared light. Accordingly, the above-described lock-in detection can be realized using a compact configuration. The VCSEL 41 is shown in FIG. 7, for the sake of convenience, in such a manner that the VCSEL 41 is inclined in a backward direction of the CMOS section 31 in order to show the circuits of the signal processor. However, in reality, it is preferable that the VCSEL 41 be placed in parallel with a surface of the silicon substrate 30, on which the CMOS section 31 is formed, as shown in FIG. 3. However, any arrangement may be used, in which the VCSEL 41 can emit modulated light to the light-receiving sections through the CMOS section 31.

Regarding each of the photodiodes 10p shown in FIG. 3, a conductivity-type configuration in which the amount of signal charge corresponding to holes is read is described as an example. In other words, each of the photodiodes 10p has the conductivity-type configuration in which the amount of signal charge corresponding to holes from a corresponding one of the p-type regions 16 is read by the CMOS section 31 for each of the picture elements. However, the photodiode 10p may have a conductivity-type configuration in which the amount of signal charge corresponding to electrons is read by the CMOS section 31 for each of the picture elements by reversing the conductivity type of each portion shown in FIG. 3. Furthermore, although a device in which CMOS circuits are used for the signal processor is described as an example in the second embodiment of the present invention, CCD circuits may be used instead of the CMOS circuits.

Although the embodiments of the present invention are described above, the above-disclosed embodiments of the present invention are only examples, and the scope of the present invention is not limited to the embodiments of the preset invention. The scope of the present invention is defined by the claims. Furthermore, any equivalent of the claims, and modifications that are made without departing from the spirit of the present invention are included.

According to any one of the embodiments of the present invention, a device can be compactly configured, which is capable of detecting a signal having a high S/N ratio even when extremely weak signal light exists in noise which is caused by the photoelectric conversion section and whose level is high. More particularly, when the device is targeted for near infrared light, the device can be produced at a low cost by utilizing existing production processes.

What is claimed is:

1. A photodiode comprising:
a sensor section that is provided on a first semiconductor having a band gap energy which allows input light having a wavelength that is in a target wavelength range to be received;
a modulated light-emitting section that is positioned behind the sensor section with respect to the input light, and that is configured to emit, to the sensor section, modulated light having a band gap energy which is higher than that of the sensor section; and
a signal processor that is formed on a second semiconductor which transmits the modulated light, and that is positioned between the sensor section and the modulated light-emitting section.

2. The photodiode according to claim 1, wherein the signal processor includes a detector, and the detector is configured to drive the modulated light-emitting section, configured to read an output that is generated in the sensor section by the input light and the modulated light, and configured to detect a signal of the input light by using lock-in detection.

3. The photodiode according to claim 1, wherein the input light that is in the target wavelength range is light that is in a near infrared range.

4. The photodiode according to claim 1, wherein the second semiconductor is silicon.

5. The photodiode according to claim 1, wherein the signal processor includes a complementary metal oxide semiconductor circuit or a charge coupled device circuit.

6. The photodiode according to claim 1, wherein the modulated light-emitting section is formed using a surface emitting device.

7. A photodiode array in which the two or more photodiodes according to claim 1 are one dimensionally or two dimensionally arranged, in which the sensor sections are formed on one common substrate of the first semiconductor, and in which the signal processor is formed on one common substrate of the second semiconductor.

8. The photodiode array according to claim 7, wherein the modulated light-emitting section is formed as one emitting section that is common to the two or more photodiodes.

9. An image pickup device for detecting a signal of input light and forming an image, the image pickup device comprising:
a plurality of light-receiving sections that are formed in a one-dimensional or two-dimensional arrangement on a light-receiving semiconductor; and
a modulated light-emitting section configured to irradiate the plurality of light-receiving sections with modulated light in such a manner that the modulated light is superimposed on the input light.

10. The image pickup device according to claim 9, wherein the modulated light is irradiated onto the plurality of light-receiving sections from a surface that is positioned on a side which is opposite a side of a surface that the input light enters.

11. The image pickup device according to claim 9, further comprising a signal processor configured to drive the modulated light-emitting section, configured to read, from each of the plurality of light-receiving sections, an output that is generated by the input light and the modulated light, and configured to detect a signal that is caused by the input light,
wherein the signal processor is formed on a semiconductor for forming a circuit transmitting the modulated light, and is positioned between the plurality of light-receiving sections and the modulated light section.

12. The image pickup device according to claim 9, wherein the light-receiving semiconductor is a semiconductor that is capable of receiving the input light which is in a near infrared range, and the semiconductor for forming a circuit is silicon.
